(19) United States
(12) Patent Application Publication
(10) Pub. No.: US 2010/0289130 A1
(43) Pub. Date: Nov. 18, 2010

(54) Method and Apparatus for Vertical Stacking of Integrated Circuit Chips

(75) Inventor: Joseph C. Fjelstad, Maple Valley, WA (US)

Correspondence Address: TPL/Interconnect Portfolio, LLC;C/O Alliacense Limited LLC, 20883 Stevens Creek Boulevard, Suite 100, Cupertino, CA, 95014, US

(73) Assignee: INTERCONNECT PORTFOLIO LLC, Cupertino, CA (US)

(21) Appl. No.: 12/464,253

(22) Filed: May 12, 2009

(51) Int. Cl. H01L 23/48; H05K 1/11; H01L 21/50

(52) U.S. Cl. 257/686; 174/261; 438/107; 257/E23.01; 257/E21.499

(57) ABSTRACT

A method and apparatus for constructing a packaged integrated circuit stack 40 having at least two packaged integrated circuits 44 and 45 with an interposer 42 between the packaged integrated circuits 44 and 45. Interposer 42 is provided with apertures 47 which allow adhesive 50 to flow through interposer 42 to bond packaged integrated circuits 44 and 45 together with interposer 42. Alternate embodiments provide holes 54 to allow passage of leads 56 through interposer 42 to a substrate 60 through additional connections 48. The method describes the construction of the stack.

### BACKGROUND OF THE INVENTION

1. Field of the Invention

The present invention relates to semiconductor device fabrication and more particularly to packaging of integrated circuit chips and with still greater particularity an interposer and method for vertical stacking of packaged integrated circuit chips.

2. Description of the Background Art

In the fabrication of semiconductor devices and electronic systems, integrated circuit chips (ICs) are conventionally encapsulated in various standard packages with protruding leads, such as thin small outline packages (TSOPs), which are adapted to be attached and connected to a substrate or circuit board using standard assembly and test techniques, such as SMT assembly and test. Use of standard packages and techniques is important for reducing the production time and cost of an electronic device or system. Stacking, or vertical assembly, of packaged ICs such as TSOPs can be advantageous to provide greater functional capability in a smaller volume, that is, greater functional density and a smaller footprint on a circuit board that supports the system.

One technique is to stack standard packaged ICs using a combination of straight leads 10 and curved leads 12 connected by solder fillets 14, as depicted in FIG. 1. Solder fillets 14 can fail under vibration.

Another stacking technique for standard IC packages, disclosed by Partridge (U.S. Pat. No. 7,375,418) as depicted in FIG. 2A, uses an interposer 16 between the leads 18 of an upper IC 20 and the leads 22 of a lower IC 24, interposer continues 26 between IC 20 and 24 for intra-stack connections within rows of leads on either side of the stack.

FIG. 2B illustrates an interposer structure offered for sale by Staktek (Entorian Technologies Inc., Austin, Tex.), wherein the interposers 16 and 17 on both sides of a stack, including an upper IC 20 and a lower IC 24, are joined by a membrane 26. The leads 18 and 22 are connected respectively to an upper trace 19 and a lower trace 23 on interposer 16 by solder fillets 28. This works well for consumer assemblies but the solder joint between packages is too weak for more rugged applications, and thus an improved stacking structure and method are desirable. There is thus a long standing need for a robust Method and Apparatus for stacking IC packages.

### SUMMARY OF INVENTION

The apparatus of the invention provides an interposer lead frame with apertures through which an adhesive material extends to form a secure bond between vertically stacked standard packaged ICs. The leads of an upper packaged IC are electrically connected to soldering lands of the interposer leads, accessible from either side of the interposer lead frame. According to one embodiment, the interposer leads are formed outward, for connection to terminals on a substrate or circuit board that are separate from the terminals to which the leads of a lower packaged IC are connected, thereby providing for selective interconnection between leads of the upper IC, and for selective connection of the interposer leads to the leads of the lower IC, implemented in the substrate. According to an alternate embodiment, the interposer leads are formed inward, for connection to the leads of the lower IC. The inventive apparatus provides improved mechanical robustness for a vertical stack of standard packaged ICs, and lower cost of implementing intra-stack selective electrical connections.

### BRIEF DESCRIPTION OF THE FIGURES

In the accompanying drawings:

FIG. 1 (PRIOR ART) is a side view of a stack of two packaged ICs connected by leads and solder fillets.

FIG. 2A (PRIOR ART) is a perspective view of a stack of two TSOP ICs with interposers and a membrane.

FIG. 2B (PRIOR ART) is sectional side view of two TSOP ICs with interposers and a membrane;

FIG. 3 is a sectional edge view of an embodiment of the apparatus of the invention.

FIG. 4 is a plan view of the interposer lead frame of the FIG. 3 embodiment.

FIG. 5 is a sectional edge view of a second embodiment of the apparatus of the invention.

FIG. 6 is a sectional edge view of a third embodiment of the apparatus of the invention.

FIG. 7 is a sectional edge view of a fourth embodiment of the apparatus of the invention.

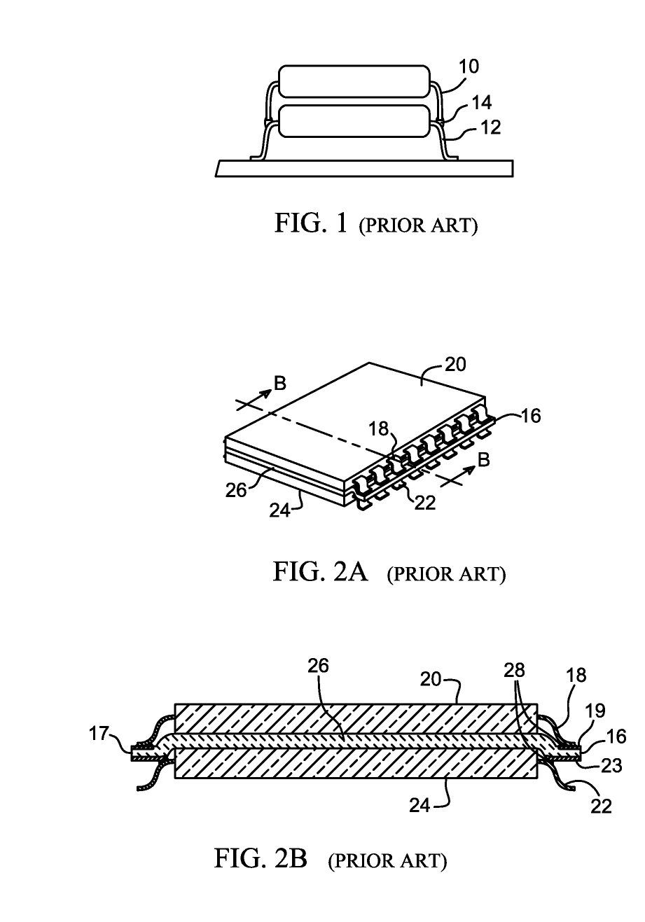

### DETAILED DESCRIPTION OF THE FIGURES

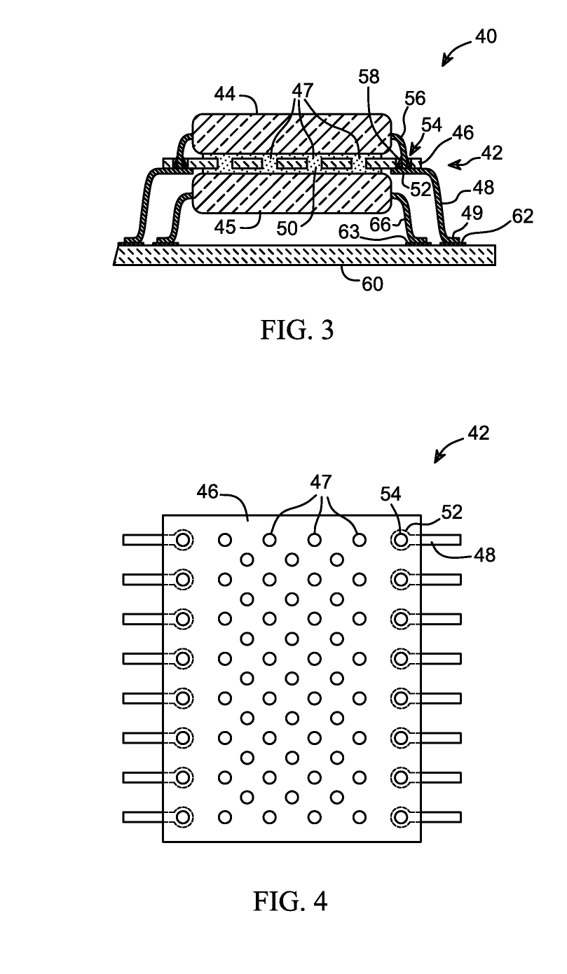

An improved vertical stack of packaged ICs, such as thin small outline packages (TSOPs), according to an embodiment of the invention is illustrated in sectional view in FIG. 3 and designated therein by the general reference character 40. The improved stack 40 includes an interposer lead frame 42 and an adhesive layer 50, disposed between an upper packaged IC 44 and a lower packaged IC 45. The interposer lead frame 42 includes an insulating base 46 having a plurality of apertures 47, and a plurality of leads 48. The adhesive layer 50 extends (flows, during assembly) through the plurality of apertures 47, provided in the base 46, and bonds the ICs securely together. The leads 48 are attached to one side of the base 46, comprising a lead frame. Each of the leads 48 has a soldering land 52 for electrical connection to the upper IC 44, and openings 54 are provided for access to the lands 52 also from the other side of the interposer. In the FIG. 3 embodiment, the leads 48 are formed outward, and a foot portion 49 of a lead 48, which extends distally away from the stack, can be connected to a terminal 62 of a substrate or circuit board 60. A lead 66 of the lower IC 45 can be connected to a different terminal 63 of the substrate or circuit board 60, which does not have to be electrically connected to the terminal 62. Thus, the leads 56 of the upper IC 44 and the leads 66 of the lower IC 45 can be connected to distinct sets of terminals 62 and 63 on the substrate or circuit board 60. Accordingly, electrical connections between selected leads 56 of the upper IC 44, and electrical connections between a selected lead 56 of the upper IC 44 and a lead 66 of the lower IC 45, can be formed in the substrate or circuit board 60 by suitable traces (not shown).

FIG. 4 is a plan view of the interposer lead frame 42 of the FIG. 3 embodiment. The insulating base 46 includes a plurality of apertures 47 which allow a liquid adhesive to penetrate insulating base 46. Apertures 47 may be a shape allowing such passage and the number of apertures 47 should be sufficient to allow such passage. FIG. 4 also depicts leads 48, soldering lands 52, and openings 54. Each of the leads 48 has a soldering land 52 for electrical connection to the upper IC 44, and openings 54 are provided for access to the lands 52 also from the other side of the interposer. A lead 56 of the upper IC 44 can be attached to a land 52 by a solder fillet 58, as shown in FIG. 3.

To assemble, a quantity of adhesive 50 is placed upon the top surface of integrated circuit chip package 45. Interposer 42 is then placed on top and pressed down, forcing adhesive 50 to flow through apertures 47 onto the top surface of interposer 42. Integrated chip package 44 is then placed on the adhesive covered top of interposer 42. When adhesive 50 sets, stack 40 is more mechanically robust than prior art stacks, as IC 44 and 45 are joined by adhesive 50. Alternatively, adhesive 50 can be applied to the bottom surface of integrated circuit package 44 first and allowed to flow through apertures 47 over the bottom surface of interposer 42 and integrated circuit 45 attached. In another alternative method, adhesive 50 may be applied to both ICs 44 and 45 before assembly. Leads 56 may then be soldered to lands 52 if desired. Accordingly, the stack 40 is more mechanically robust than prior art stacks, as the ICs are joined by an adhesive, in addition to solder fillets on the leads. The stack 40 is more economical, as intra-stack connections can be implemented in the substrate, by means of substrate or circuit board technology, rather than in the interposer itself.

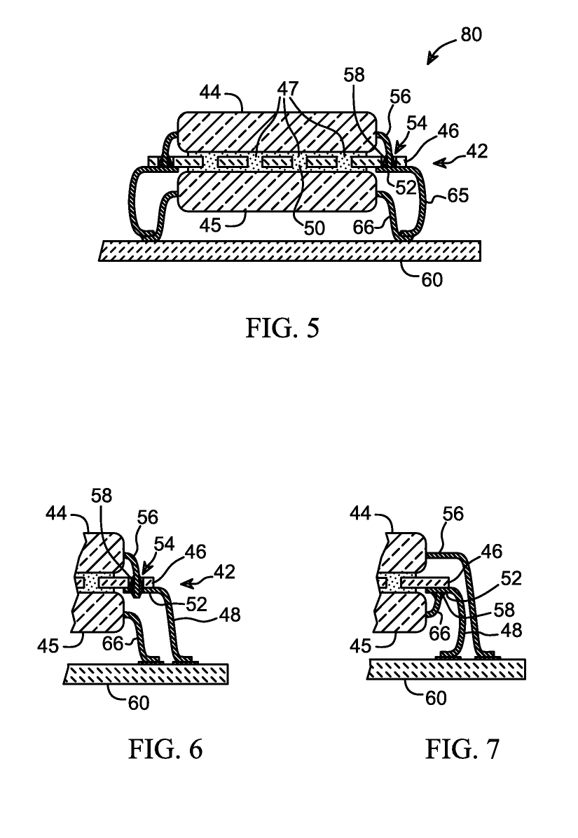

An alternate embodiment of a stack 80 of packaged ICs is illustrated in FIG. 5. In the stack 80, the leads 65 of the interposer 42 are formed inward, and connected to the leads 66 of the lower IC 45, for example by solder fillets. The component parts of the stack 80 which are substantially similar to the parts of the stack 40 and described hereinabove in conjunction with FIGS. 3-4, are identified by the same reference numerals in FIG. 5, as in FIGS. 3-4. The FIG. 5 embodiment can be advantageous in applications wherein the stacked ICs are electrically connected in parallel. The FIG. 3 embodiment, on the other hand, allows selective interconnections between the leads 56 of the upper IC, and selective connection to the leads 66 of the lower IC, by means of suitable traces (not shown) in the substrate 60.

To assemble, a quantity of adhesive 50 is placed upon the top surface of integrated circuit chip package 45. Interposer 42 is then placed on top and pressed down, forcing adhesive 50 to flow through apertures 47 onto the top surface of interposer 42. Integrated chip package 44 is then placed on the adhesive covered top of interposer 42. When adhesive 50 sets, stack 40 is more mechanically robust than prior art stacks, as IC 44 and 45 are joined by adhesive 50. Alternatively, adhesive 50 can be applied to the bottom surface of integrated circuit package 44 first and allowed to flow through apertures 47 over the bottom surface of interposer 42 and integrated circuit 45 attached. In another alternative method, adhesive 50 may be applied to both ICs 44 and 46 before assembly. Leads 56 may then be soldered to lands 52 if desired. Finally, leads 66 and 48 may be attached to a circuit board 60 by solder or other means. The stack 40 is more economical, as intra-stack connections can be implemented in the substrate, by means of substrate or circuit board technology, rather than in the interposer itself.

FIG. 6 is a sectional edge view of a third embodiment of the apparatus of the invention. In this embodiment, leads 56 of top packaged integrated circuit 44 pass through a hole 54 in the insulating portion 46 of interposer 42. Lead 56 there connects to a land 52 which may be means of solder fillet 58. Land 52, in turn, is connected to a lead 48 which connects to substrate 60. Bottom packaged integrated circuit 45 leads 66 connect directly to substrate 60.

FIG. 7 is a sectional edge view of a fourth embodiment of the apparatus of the invention. In this embodiment, the leads 56 of top packaged integrated circuit 44 connect directly to substrate 60. Leads 66 of bottom packaged integrated circuit 45 connect to ancillary leads 48 by means of solder fillets 58 to soldering lands 52 on insulating base 46 which, in turn, connect to substrate 60.

Although the invention has been described with reference to specific exemplary embodiments, it will be evident that various modifications and changes may be made thereto without departing from the broader spirit and scope of the invention as set forth in the appended claims. The specification and drawings are, accordingly, to be regarded in an illustrative rather than a restrictive sense.

### INDUSTRIAL APPLICABILITY

The inventive stacks 40, interposers 42, adhesive layers 50, insulating bases 46 apertures 47, leads 48 and method for fabricating the device are intended to be widely used in a great variety of electronic and communication applications. It is expected that they will be particularly useful in applications where significant resistance to vibration and mechanical impact are required.

As discussed previously herein, the applicability of the present invention is such that the economic savings and great strength are enhanced. The inventive stacks 40, interposers 42, adhesive layers 50, insulating bases 46 apertures 47, leads 48 and method for fabricating the device may be readily produced and integrated with existing tasks, devices and the like, and since the advantages as described herein are provided, it is expected that they will be readily accepted in the industry. For these and other reasons, it is expected that the utility and industrial applicability of the invention will be both significant in scope and long-lasting in duration.

1. A packaged integrated circuit stack comprising: a first packaged integrated circuit chip having leads; and, a second packaged integrated circuit chip having leads, vertically stacked below the first chip; and, an interposer frame including an insulating base having apertures, disposed between said first and said second packaged integrated circuit chips.

2. A packaged integrated circuit stack as in claim 1, further comprising an adhesive material extending through said apertures and attached to said first and said second packaged integrated circuit chips.

3. A packaged integrated circuit stack as in claim 1, wherein said interposer frame further comprises a plurality of leads.

4. A packaged integrated circuit stack as in claim 3, further comprising a soldering land attached to one side of said interposer frame.

5. A packaged integrated circuit stack as in claim 3, wherein said interposer frame further comprises an opening providing access for electrical contact to said soldering land from one side of said insulating base to the other side of said insulating base.

6. A packaged integrated circuit stack as in claim 3, wherein a lead of said first packaged integrated circuit chip is electrically connected to a lead of the interposer lead frame.

7. A packaged integrated circuit stack as in claim 3, wherein the leads of the interposer lead frame are formed outward.

8. A packaged integrated circuit stack as in claim 7, further comprising a substrate having first and second sets of terminals, wherein an outward-formed lead is electrically connected to a terminal of said first set of terminals.

9. A packaged integrated circuit stack as in claim 8, wherein a lead of said second packaged integrated circuit chip is electrically connected to a terminal of said second set of terminals.

10. A packaged integrated circuit stack as in claim 9, further comprising a trace on said substrate for providing an electrical connection between at least two terminals of the first set.

11. A packaged integrated circuit stack as in claim 10, further comprising a trace on said substrate for an electrical connection between a terminal of said first set of terminals and a terminal of said second set of terminals.

12. A packaged integrated circuit stack as in claim 4, wherein the leads of said interposer lead frame are formed inward and electrically connected to the leads of said second packaged integrated circuit chip.

13. An interposer for imposition between two packaged integrated circuits comprising: a substantially planer top surface; and, a substantially planer bottom surface; and, an insulating material interposed between said top surface and said bottom surface; and, a plurality of apertures in said insulating surface for providing a path for adhesive to flow between said top surface and said bottom surface.

14. An interposer as in claim 13, further comprising a plurality of leads.

15. An interposer as in claim 13, further comprising a soldering land attached to one side of said interposer.

16. An interposer as in claim 15, wherein said interposer further comprises an opening providing access for electrical contact to said soldering land from said first top planer surface to said planer bottom surface.

17. A method for constructing a packaged integrated stack comprising the steps of, providing a first packaged integrated circuit, and, applying adhesive to a surface of said first packaged integrated circuit, and, placing an interposer having a plurality of openings in such a manner that adhesive flows through said apertures, and, further providing a second packaged integrated circuit in such a manner that adhesive which has flowed through said apertures contacts a surface of said second packaged integrated circuit, and, setting said adhesive to form a stack with said interposer bonded with adhesive between said first and said second packaged integrated circuits.

18. A method for constructing a packaged integrated stack as in claim 17, wherein said first and said second packaged integrated circuits are provided with leads further comprising; the step of inserting the leads of one of said packaged integrated circuits through apertures in said interposer.

19. A method for constructing a packaged integrated stack as in claim 17, wherein said first and said second packaged integrated circuits are provided with leads further comprising; the step of attaching said leads to a substrate.

20. A method for constructing a packaged integrated stack as in claim 19, wherein said attaching step is by soldering.

21. A method for constructing a packaged integrated stack as in claim 18, further comprising; the step of inserting the leads of one of said packaged integrated circuits through apertures in said interposer and attaching said leads to a substrate and attaching said leads of said other packaged integrated circuit to said substrate.
